(19) United States
(12) Patent Application Publication
(10) Pub. No.: US 2009/0137097 A1
(43) Pub. Date: May 28, 2009

(54) METHOD FOR DICING WAFER

(75) Inventors: Chu-Fu Lin, Kaohsiung City (TW); Kai-Kuang Ho, Hsinchu City (TW); Kuo-Ming Chen, Hsinchu County (TW)

Correspondence Address: J C PATENTS, INC., 4 VENTURE, SUITE 250, IRVINE, CA, 92618, US

(73) Assignee: UNITED MICROELECTRONICS CORP., Hsinchu (TW)

(21) Appl. No.: 11/945,115

(22) Filed: Nov. 26, 2007

(51) Int. Cl. H01L 21/00

(52) U.S. Cl. 438/462; 257/E21.532

(57) ABSTRACT

A method for dicing a wafer including the following steps is provided. First, a carrier tape is attached to a first side of the wafer. Then, a patterned photoresist layer exposing a scribe line region of the wafer is formed on a second side of the wafer, in which the second side is the opposite side of the first side. After that, a cutting process is performed to the scribe line region from the second side of the wafer to the first side of the wafer through non-mechanical force.

### BACKGROUND OF THE INVENTION

1. Field of the Invention

The present invention relates to a method for fabricating a semiconductor. More particularly, the present invention relates to a method for dicing a wafer.

2. Description of Related Art

With rapid development of science and technology, integrated circuits (ICs) have been widely used in people's daily life. Generally speaking, the fabrication of ICs mainly has three stages: the fabricating of silicon wafers, the fabricating of ICs, and the IC packaging. For the IC packaging, the very first step is die sawing.

In a conventional art, a common wafer dicing method cuts the wafer along a scribe line in a mechanical way, for example, by the use of a diamond blade, so as to dice the wafer into a plurality of dies. However, when the width of the scribe line is smaller than 50 μm, the mechanical cutting process may cause physical damages such as chipping, peeling, or delamination to the scribe line.

Due to the continual improvements to the integrity of semiconductors, it is the trend to reduce a device dimension to increase the number of the devices produced by each wafer. However, as limited by the diamond blade, a width of at least about 50 μm must be preserved for the scribe line in the process, so that the scribe line cannot be reduced in size, leading to a waste of space. Moreover, bits and small pieces will be produced during the mechanical cutting process, and must be continually rinsed with clean water.

In another aspect, a laser cutting process is employed for dicing a wafer in a conventional art. However, much debris may be produced on the wafer when the wafer is under laser cutting, so a water-soluble film must be formed on the wafer before cutting so as to protect the wafer, thus increasing the fabrication cost. Moreover, when a low-energy laser cutting machine is adopted for cutting, as the energy of the laser is insufficient, the wafer must be cut at least twice to be cut through, so that the cutting speed is low. Therefore, the laser cutting must be implemented in conjunction with a mechanical way to enhance the production efficiency.

Definitely, currently, a high-energy laser cutting machine is available to cut through a wafer at one attempt. However, due to the high price, the high-power laser cutting machine is less preferred in the cutting process of a wafer.

### SUMMARY OF THE INVENTION

Accordingly, the present invention is directed to a method for dicing a wafer, so as to prevent any damage to the wafer during dicing.

The present invention is also directed to a method for dicing a wafer, so as to effectively cut along a scribe line with smaller width.

The present invention is further directed to a method for dicing a wafer, so as to improve the speed of die sawing.

The present invention provides a method for dicing a wafer, which includes the following steps. First, a carrier tape is attached to a first side of the wafer. Then, a patterned photoresist layer exposing a scribe line region of the wafer is formed on a second side of the wafer, wherein the second side is the opposite side of the first side. After that, a cutting process is performed to the scribe line region from the second side of the wafer to the first side of the wafer through non-mechanical force.

In the method for dicing a wafer according to an embodiment of the present invention, the carrier tape is a blue tape or a UV tape.

In the method for dicing a wafer according to an embodiment of the present invention, the first side and the second side are respectively a front side or a back side of the wafer.

In the method for dicing a wafer according to an embodiment of the present invention, a process for forming the patterned photoresist layer includes a photolithography process.

In the method for dicing a wafer according to an embodiment of the present invention, the implementation method of the non-mechanical force is one selected from a group consisted of a dry etching process, a wet etching process, and laser cutting process, or any combination thereof.

In the method for dicing a wafer according to an embodiment of the present invention, the method for dicing a wafer further includes removing the patterned photoresist layer after the cutting process.

The present invention further provides a method for dicing a wafer. The wafer includes a substrate and a plurality of material layers disposed on the substrate. The material layers are disposed on a front side of the wafer, and a back side of the wafer is the opposite side of the front side. The method includes the following steps. First, a carrier tape is attached to the back side of the wafer. Then, a patterned photoresist layer exposing a scribe line region of the wafer is formed on the front side of the wafer. After that, a first cutting process is performed on the scribe line region from the front side of the wafer until exposing the substrate of the wafer through laser cutting. Then, a second cutting process is performed on the scribe line region from the front side of the wafer to the back side of the wafer through etching.

In the method for dicing a wafer according to another embodiment of the present invention, the carrier tape is a blue tape or a UV tape.

In the method for dicing a wafer according to another embodiment of the present invention, a process for forming the patterned photoresist layer includes a photolithography process.

In the method for dicing a wafer according to another embodiment of the present invention, the etching is dry etching or wet etching.

In the method for dicing a wafer according to another embodiment of the present invention, the method for dicing a wafer further includes removing the patterned photoresist layer after the second cutting process.

The present invention further provides a method for dicing a wafer. The wafer includes a substrate and a plurality of material layers disposed on the substrate. The material layers are disposed on a front side of the wafer, and a back side of the wafer is the opposite side of the front side. The method includes the following steps. First, a carrier tape is attached to the front side of the wafer. Then, a patterned photoresist layer exposing a scribe line region of the wafer is formed on the back side of the wafer. After that, a first cutting process is performed on the scribe line region from the back side of the wafer until exposing the material layers of the wafer through etching. Then, a second cutting process is performed on the scribe line region from the back side of the wafer to the front side of the wafer through laser cutting.

In the method for dicing a wafer according to still another embodiment of the present invention, the carrier tape is a blue tape or a UV tape.

In the method for dicing a wafer according to still another embodiment of the present invention, the method for dicing a wafer further includes polishing the back side of the wafer after the carrier tape is attached and before the patterned photoresist layer is formed.

In the method for dicing a wafer according to still another embodiment of the present invention, a process for forming the patterned photoresist layer includes a photolithography process.

In the method for dicing a wafer according to still another embodiment of the present invention, the etching is dry etching or wet etching.

In the method for dicing a wafer according to still another embodiment of the present invention, the method for dicing a wafer further includes removing the patterned photoresist layer after the first cutting process and before the second cutting process.

In the method for dicing a wafer according to still another embodiment of the present invention, the method for dicing a wafer further includes removing the patterned photoresist layer after the second cutting process.

In view of the above, the method for dicing a wafer provided by the present invention employs a cutting process of the non-mechanical force to dice a wafer, thereby effectively cutting along a scribe line with smaller width, and preventing any damage to the wafer during dicing.

Further, when the method for dicing a wafer provided by the present invention is carried out together with the laser cutting and etching processes, the speed of die sawing can be effectively improved.

In order to make the aforementioned and other objectives, features, and advantages of the present invention comprehensible, embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart of a method for dicing a wafer according to a first embodiment of the present invention.

FIG. 2 is a flow chart of a method for dicing a wafer according to a second embodiment of the present invention.

FIG. 3 is a flow chart of a method for dicing a wafer according to a third embodiment of the present invention.

### DESCRIPTION OF EMBODIMENTS

Definitions of the “front side” and “back side” of a wafer are first explained. During the semiconductor process, when entering the dicing stage, the wafer has a substrate and various devices composed of a plurality of material layers disposed on the substrate. Here, the front side of the wafer is defined as a side on which the various devices composed of the material layers are disposed, and the back side of the wafer is defined as the opposite side of the front side, i.e., a side without any devices. Wherein, the material layers disposed on the substrate includes various devices such as MOSFET, capacitor, resistor, metal interconnection, inductor, test key or monitor pad, etc. Besides, the wafer could comprise material layers stacked on the back side of the wafer during device fabricating, and the material layers on the back side of the wafer could be removed by washing during the device fabricating process or by polishing the wafer. Furthermore, the “scribe line region” described in the description is the scribe line region of the front side of the wafer or the region of the back side of the wafer corresponding to the scribe line region of the front side of the wafer.

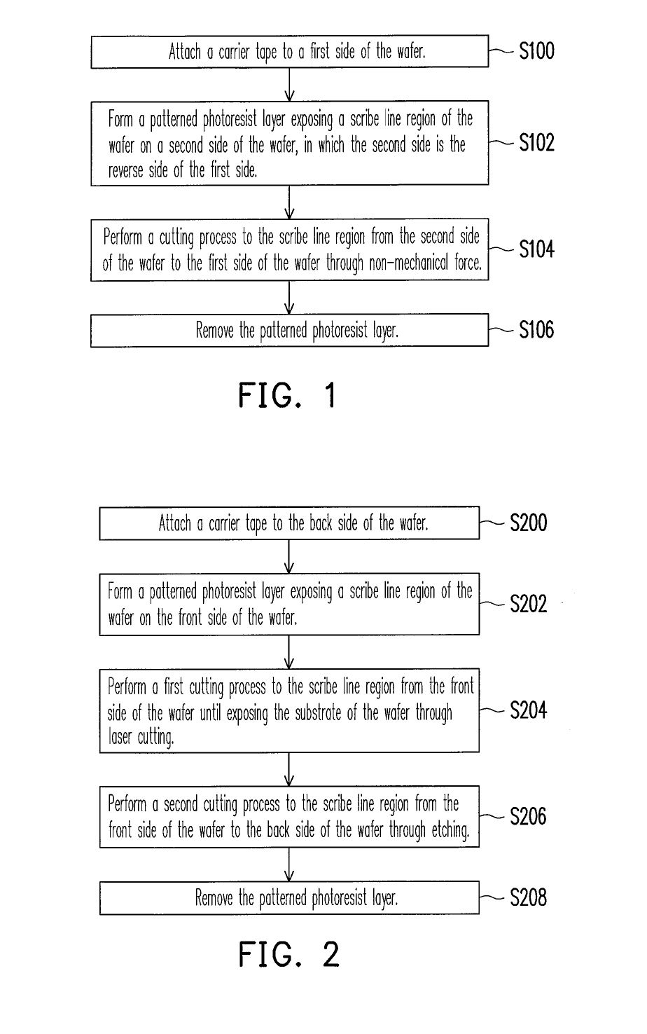

FIG. 1 is a flow chart of a method for dicing a wafer according to a first embodiment of the present invention.

Referring to FIG. 1, first, in Step S100, a carrier tape is attached to a first side of the wafer, so as to carry the wafer, and also to prevent a mass of dies from scattering after dicing. The first side of the wafer can be the front side or back side of the wafer. The carrier tape is, for example, but not limited to, a blue tape or a UV tape.

Next, in Step S102, a patterned photoresist layer exposing a scribe line region of the wafer is formed on a second side of the wafer, in which the second side is the opposite side of the first side. The scribe line region is a region where the scribe line is formed on the wafer, i.e., a region to be cut on the wafer. The second side of the wafer can be the front side or back side of the wafer. The method for forming the patterned photoresist layer is, for example, photolithography.

Then, in Step S104, a cutting process is performed on the scribe line region from the second side of the wafer to the first side of the wafer through non-mechanical force. The implementation method of the non-mechanical force is one selected from a group consisted of a dry etching process, a wet etching process, and a laser cutting process, or any combination thereof.

Afterwards, in Step S106, the patterned photoresist layer is removed. The method for removing the patterned photoresist layer is, for example, ashing.

It should be noted that the back side of the wafer could be polished after the carrier tape is attached to the front side of the wafer and before the patterned photoresist layer is formed, so as to reduce the thickness of the substrate and remove the material layers stacked on the back side of the wafer during device fabricating, which contributes to the dicing and subsequent packaging process.

Seen from the above embodiment, the wafer is diced in a non-mechanical force way, thus preventing physical damages such as chipping, peeling, or delamination to the scribe line, and effectively cutting along a scribe line with smaller width.

Moreover, when the patterned photoresist layer is removed after the wafer is diced through laser cutting, the patterned photoresist layer can prevent debris produced during laser cutting from damaging the wafer.

Further, when the method for dicing a wafer provided by the present invention is carried out together with the laser cutting and etching processes, the speed of die sawing can be effectively improved.

FIG. 2 is a flow chart of a method for dicing a wafer according to a second embodiment of the present invention.

Referring to FIG. 2, first, in Step S200, a carrier tape is attached to the back side of the wafer, so as to carry the wafer, and also to prevent a mass of dies from scattering after dicing. The carrier tape is, for example, but not limited to, a blue tape or a UV tape.

Next, in Step S202, a patterned photoresist layer exposing a scribe line region of the wafer is formed on the front side of the wafer. The scribe line region is a region where the scribe line is formed on the wafer, i.e., a region to be cut on the wafer. The method for forming the patterned photoresist layer is, for example, photolithography.

Afterwards, in Step S204, a first cutting process is performed on the scribe line region from the front side of the wafer until exposing the substrate of the wafer through laser cutting. The first cutting process is mainly performed to cut the plurality of material layers on the substrate. If the material layers on the substrate are cut through etching, as the materials of the material layers may be different, it is rather time-consuming to adjust parameters of the etching process according to the material of each of the material layers. As the material layers on the substrate can be directly cut through by laser cutting, the speed of wafer dicing can be improved.

Next, in Step S206, a second cutting process is performed on the scribe line region from the front side of the wafer to the back side of the wafer through etching, i.e., to cut through the wafer. The etching is, for example, dry etching or wet etching. The second cutting process is mainly performed to cut the substrate of the wafer. As the laser cutting process is slower than the etching process in cutting the substrate, the etching process is adopted to cut the substrate, so as to improve the speed of wafer dicing.

Thereafter, in Step S208, the patterned photoresist layer is removed. The method for removing the patterned photoresist layer is, for example, ashing.

Seen from the above, the wafer is diced in a non-mechanical force way, thus preventing physical damages to the wafer, and effectively cutting along a scribe line with smaller width.

Moreover, the patterned photoresist layer is removed after the wafer is diced through laser cutting, so the patterned photoresist layer can prevent debris produced during laser cutting from damaging the wafer.

Further, the laser cutting process or the etching process is selected for different objects, thus effectively improving the speed of die sawing.

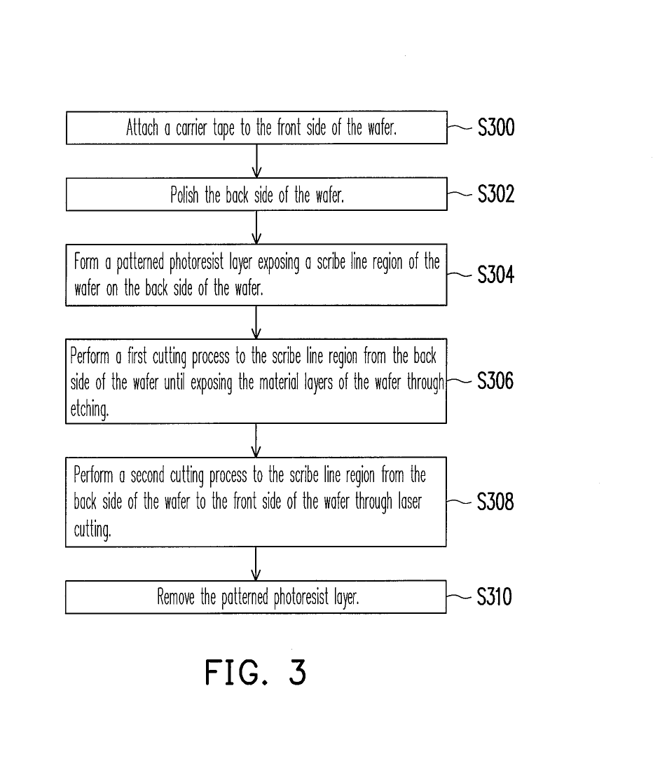

FIG. 3 is a flow chart of a method for dicing a wafer according to a third embodiment of the present invention.

Referring to FIG. 3, first, in Step S300, a carrier tape is attached to the front side of the wafer, so as to carry the wafer, and also to prevent a mass of dies from scattering after dicing. The carrier tape is, for example, but not limited to, a blue tape or a UV tape.

Then, in Step S302, optionally, a polishing process is performed on the back side of the wafer, so as to reduce the thickness of the substrate, which contributes to the dicing and subsequent packaging process.

After that, in Step S304, a patterned photoresist layer exposing a scribe line region of the wafer is formed on the back side of the wafer. The scribe line region is a region where the scribe line is formed on the wafer, i.e., a region to be cut on the wafer. The method for forming the patterned photoresist layer is, for example, photolithography.

Next, in Step S306, a first cutting process is performed on the scribe line region from the back side of the wafer until exposing the material layers of the wafer through etching. The etching is, for example, dry etching or wet etching. The first cutting process is mainly performed to cut the substrate of the wafer. As the laser cutting process is slower than the etching process in cutting the substrate, the substrate is cut by etching, so as to improve the speed of wafer dicing.

Thereafter, in Step S308, a second cutting process is performed on the scribe line region from the back side of the wafer to the front side of the wafer through laser cutting, i.e., to cut through the wafer. The second cutting process is mainly performed to cut the plurality of material layers on the substrate. If the material layers on the substrate are cut by etching, as the materials of the material layers may be different, it is rather time-consuming to adjust parameters of the etching process according to the material of each of the material layers. As the material layers on the substrate can be directly cut through by laser cutting, the speed of wafer dicing is improved.

Then, in Step S310, the patterned photoresist layer is removed. The method for removing the patterned photoresist layer is, for example, ashing. In another embodiment, the patterned photoresist layer is removed after the first cutting process and before the second cutting process, but the effect on protecting the wafer is unsatisfactory.

Seen from the above, the wafer is diced in a non-mechanical force way, thus preventing physical damages to the wafer, and effectively cutting along a scribe line with smaller width.

Moreover, when the patterned photoresist layer is removed after the wafer is diced through laser cutting, the patterned photoresist layer can prevent debris produced during laser cutting from damaging the wafer.

Further, the method for dicing the wafer is carried out together with the laser cutting and etching processes. Wherein, the laser cutting process or the etching process is selected for different objects, so as to effectively improve the speed of die sawing.

In view of the above, the aforementioned embodiments at least have the following advantages.

1. The method for dicing a wafer according to the above embodiments can effectively cut along a scribe line with smaller width.

2. The method for dicing a wafer according to the above embodiments can prevent damages to the wafer during wafer dicing.

3. The method for dicing a wafer according to the above embodiments can improve the speed of die sawing.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for dicing a wafer, comprising:
attaching a carrier tape to a first side of the wafer;
forming a patterned photoresist layer exposing a scribe line region of the wafer on a second side of the wafer, wherein the second side is the opposite side of the first side; and
performing a cutting process to the scribe line region from the second side of the wafer to the first side of the wafer through non-mechanical force.

2. The method for dicing a wafer as claimed in claim 1, wherein the carrier tape is a blue tape or a UV tape.

3. The method for dicing a wafer as claimed in claim 1, wherein the first side and the second side are respectively a front side or a back side of the wafer.

4. The method for dicing a wafer as claimed in claim 1, wherein a process for forming the patterned photoresist layer comprises a photolithography process.

5. The method for dicing a wafer as claimed in claim 1, wherein the implementation method of the non-mechanical force is one selected from a group consisted of a dry etching process, a wet etching process, and a laser cutting process, or any combination thereof.

6. The method for dicing a wafer as claimed in claim 1, further comprising removing the patterned photoresist layer after the cutting process.

7. A method for dicing a wafer, wherein the wafer comprises a substrate and a plurality of material layers disposed on the substrate, the material layers are disposed on a front side of the wafer, and a back side of the wafer is the opposite side of the front side, the method comprising:
attaching a carrier tape to the back side of the wafer;
forming a patterned photoresist layer exposing a scribe line region of the wafer on the front side of the wafer;
performing a first cutting process on the scribe line region from the front side of the wafer until exposing the substrate of the wafer through laser cutting; and
performing a second cutting process on the scribe line region from the front side of the wafer to the back side of the wafer through etching.

8. The method for dicing a wafer as claimed in claim 7, wherein the carrier tape is a blue tape or a UV tape.

9. The method for dicing a wafer as claimed in claim 7, wherein a process for forming the patterned photoresist layer comprises a photolithography process.

10. The method for dicing a wafer as claimed in claim 7, wherein the etching is dry etching or wet etching.

11. The method for dicing a wafer as claimed in claim 7, further comprising removing the patterned photoresist layer after the second cutting process.

12. A method for dicing a wafer, wherein the wafer comprises a substrate and a plurality of material layers disposed on the substrate, the material layers are disposed on a front side of the wafer, and a back side of the wafer is the opposite side of the front side, the method comprising:
attaching a carrier tape to the front side of the wafer;
forming a patterned photoresist layer exposing a scribe line region of the wafer on the back side of the wafer;
performing a first cutting process on the scribe line region from the back side of the wafer until exposing the material layers of the wafer through etching; and
performing a second cutting process on the scribe line region from the back side of the wafer to the front side of the wafer through laser cutting.

13. The method for dicing a wafer as claimed in claim 12, wherein the carrier tape is a blue tape or a UV tape.

14. The method for dicing a wafer as claimed in claim 12, further comprising performing a polishing process on the back side of the wafer after the carrier tape is attached and before the patterned photoresist layer is formed.

15. The method for dicing a wafer as claimed in claim 12, wherein a process for forming the patterned photoresist layer comprises a photolithography process.

16. The method for dicing a wafer as claimed in claim 12, wherein the etching is dry etching or wet etching.

17. The method for dicing a wafer as claimed in claim 12, further comprising removing the patterned photoresist layer after the first cutting process and before the second cutting process.

18. The method for dicing a wafer as claimed in claim 12, further comprising removing the patterned photoresist layer after the second cutting process.
